(19) United States
(12) Patent Application Publication
(10) Pub. No.: US 2024/0076099 A1
(43) Pub. Date: Mar. 7, 2024

(54) METHOD AND SYSTEM FOR MANUFACTURING A CUSTOM BOX

(71) Applicant: Jens Malmborg, Mesa, AZ (US)

(72) Inventor: Jens Malmborg, Mesa, AZ (US)

(21) Appl. No.: 18/243,163

(22) Filed: Sep. 7, 2023

Related U.S. Application Data
(60) Provisional application No. 63/404,248, filed on Sep. 7, 2022.

(51) Int. Cl. B65D 6/26; B65D 6/02; G06F 30/10; G06F 30/20

(52) U.S. Cl. CPC B65D 7/30; B65D 7/06; G06F 30/10; G06F 30/20

(57) ABSTRACT

The present is a custom storage box comprising a bottom member wherein the bottom member can be attached to at least one first side member creating a width of the box and at least one second side member creating a depth to the box wherein the first side member and second side member can be substantially the same height. The method of creating a custom storage box comprising inputting custom dimension of a box by a user into a program on a first computing device wherein the user can choose a material type and an accessory type creating the user's customized user information. Submitting the user's information to the program wherein the user's information is uploaded onto a second computing device. Converting dimensions of the box into a flat pattern. Creating a computer-aided manufacturing file from the flat pattern.

### CROSS REFERENCE TO RELATED APPLICATION

This application claims benefit from currently pending U.S. Provisional Application No. 63/404,248 titled “Method for Manufacturing a Custom Box” and having a filing date of Sep. 7, 2022, all of which is incorporated by reference herein.

### FIELD OF THE INVENTION

The present specification relates generally to method for manufacturing a box, and even more in particular, embodiments of the invention relate to a box that a consumer can order custom to their application and ship flat.

### BACKGROUND OF THE INVENTION

Custom storage boxes exist in the market today but are typically very expensive to manufacture. For example, truck bed boxes commonly known as a saddle box are usually manufactured to fit in a certain truck's make and model bed. These boxes generally have a single or two-part lid that opens on a hinge that extends the width of the truck bed. These truck bed boxes can be configured in various manners to suit the user's needs such as adding storage bins inside the truck box, adding interior shelves or tool holders providing easy access for the user. Truck boxes are commonly supported by the truck's side walls and extend vertically from the truck's side walls to the bed. The truck box usually will extend from the front of the truck bed to the forward portion of the rear wheel well and is usually attached to the side walls or to the bed of the truck through fasteners or truck mounts. As the demand for customization and utility in automotive accessories has increased, various approaches to manufacturing custom truck bed boxes have been developed. However, these conventional methods and systems have their own set of limitations, prompting the need for innovation in this field.

Typically, these truck boxes extend beyond the top of the truck's side walls making it impossible for a truck bed cover to be put over the truck bed. Because these types of storage boxes are large and heavy, manufacturers usually will have to weld all the components of the storage box together and ship the unit has a whole. Shipping these fully manufactured storage boxes can be expensive and cost prohibitive. For example, shipping internationally and trans continentally a manufacturer can use a pre-sized shipping container that will transport multiple boxes at once. However, when shipping a single box to an end user this is not possible costing the end user a large amount in shipping. Some custom truck bed boxes in the related art are constructed using welded metal components. While this approach can provide durability, it may lack flexibility in terms of design changes and may not readily accommodate a variety of materials, limiting the range of customization options available to users.

Another example are standard boxes that a user can purchase in a hardware store, or nursery for planting a garden, for storage or for other types of boxes used at home. These types of boxes are sized to a specific manufacturer's specifications and custom storage boxes are very expensive and are not a cost-effective solution for most consumers. Individuals that have an area that a standard box size will not fit into can order a custom box, but these boxes are usually expensive because of the manufacturing process. Existing manufacturing methods may impose design limitations, making it challenging to produce boxes that fully utilize the available space, fit snugly within the required space, and incorporate innovative features such as drawers, dividers, or locking mechanisms.

These limitations in the related art highlight the opportunity for innovation in the field of custom box manufacturing. The need for a method and system that can efficiently produce highly customized, durable, and resource-efficient boxes, while addressing the challenges mentioned above, is evident in the industry. The present invention aims to overcome these limitations and offer a novel approach to manufacturing boxes that caters to the diverse requirements of users.

### BRIEF SUMMARY OF THE INVENTION

Accordingly, the present is a custom storage box comprising a bottom member wherein the bottom member can be attached to at least one first side member creating a width of the box and at least one second side member creating a depth to the box wherein the first side member and second side member can be substantially the same height. At least one attachment brackets wherein the attachment brackets can have a plurality of first holes. A plurality of second holes can be located on the bottom member, first side member, and second side member wherein the plurality of first holes aligns with the plurality of second holes wherein a plurality of fasteners attaches the bottom member to the first side member and the second side member forming the box.

The at least one support can be located and attached to the bottom member. The bottom member, first side member and second side member are sheet metal having a thickness of 0.025 to 0.190. The attachment brackets can be l-shaped rails, or corner brackets. The custom storage box can have a material type wherein the material type is stainless steel, aluminum, plastic or carbon steel. The attachment brackets can be stainless steel, aluminum, or carbon steel. The width and depth of the bottom member, first side member and second side member are chosen by a user. The attachment brackets can be cut to the substantially same dimension of the width, depth and height of the box. The at least one support can be a solid or l-shape metal piece.

The method of creating a custom storage box comprising inputting custom dimension of a box by a user into a program on a first computing device wherein the user can choose a material type and an accessory type creating the user's customized user information. Submitting the user's information to the program wherein the user's information is uploaded onto a second computing device. Converting dimensions of the box into a flat pattern. Creating a computer-aided manufacturing file from the flat pattern. Loading a machine with the chosen material type by the user. Cutting the dimension on the material.

Removing the cut material from the machine and placing material into a packaging box. Placing accessories in packaging box and shipping custom box to the user wherein the user puts together the box when received. The first computing device and the second computing device can be portable computing device, laptop computer, desktop computer, or smartphone. The machine can be a waterjet, laser cutting, machining center, or the like. The material type is stainless steel, aluminum, plastic or carbon steel. The program can be on the world-wide web. The computer-aided manufacturing software can be located on the secondary computer or a third computer in which the computer-aided manufacturing software and machine are attached to.

It is advantageous to have a storage box that the user can specify the dimension for the width, depth, and height for their specific application.

It is another advantage for a user to choose the size and specifications of the box and have it easily shipped as a flat pattern to the user.

Aspects and applications of the invention presented here are described below in the drawings and detailed description of the invention. Unless specifically noted, it is intended that the words and phrases in the specification and the claims be given their plain, ordinary, and accustomed meaning to those of ordinary skill in the applicable arts. The inventors are fully aware that they can be their own lexicographers if desired. The inventors expressly elect, as their own lexicographers, to use only the plain and ordinary meaning of terms in the specification and claims unless they clearly state otherwise and then further, expressly set forth the. Absent such clear statements of intent to apply a “special” definition, it is the inventor's intent and desire that the simple, plain, and ordinary meaning to the terms be applied to the interpretation of the specification and claims.

The inventors are also aware of the normal precepts of English grammar. Thus, if a noun, term, or phrase is intended to be further characterized, specified, or narrowed in some way, then such noun, term, or phrase will expressly include additional adjectives, descriptive terms, or other modifiers in accordance with the normal precepts of English grammar. Absent the use of such adjectives, descriptive terms, or modifiers, it is the intent that such nouns, terms, or phrases be given their plain, and ordinary English meaning to those skilled in the applicable arts as set forth above.

Further, the inventors are fully informed of the standards and application of the special provisions of 35 U.S.C. § 112 (f). Thus, the use of the words “function,” “means” or “step” in the Detailed Description or Description of the Drawings or claims is not intended to somehow indicate a desire to invoke the special provisions of 35 U.S.C. § 112 (f), to define the invention. To the contrary, if the provisions of 35 U.S.C. § 112 (f) are sought to be invoked to define the inventions, the claims will specifically and expressly state the exact phrases “means for” or “step for” and will also recite the word “function” (i.e., will state “means for performing the function of . . . , without also reciting in such phrases any structure, material or act in support of the function. Thus, even when the claims recite a “means for performing the function of molding a . . . , step for performing the function of molding a . . . ,” if the claims also recite any structure, material or acts in support of that means or step, or that perform the recited function, then it is the clear intention of the inventors not to invoke the provisions of 35 U.S.C. § 112 (f). Moreover, even if the provisions of 35 U.S.C. § 112 (f) are invoked to define the claimed inventions, it is intended that the inventions not be limited only to the specific structure, material or acts that are described in the preferred embodiments, but in addition, include any and all structures, materials or acts that perform the claimed function as described in alternative embodiments or forms of the invention, or that are well known present or later-developed, equivalent structures, material or acts for performing the claimed function.

Additional features and advantages of the present specification will become apparent to those skilled in the art upon consideration of the following detailed description of the illustrative embodiment exemplifying the best mode of carrying out the invention as presently perceived.

### BRIEF DESCRIPTION OF THE DRAWINGS

These and other features, aspects, and advantages of the present specification will become better understood with regard to the following description, appended claims, and accompanying drawings where:

FIG. 1 is an isometric view of the custom box system in accordance to one, or more embodiments;

FIG. 2 is a front view of the custom box system in accordance to one, or more embodiments;

FIG. 3 is a back view of the custom box system in a truck bed in accordance to one, or more embodiments;

FIG. 4 is a front view of the custom box system boxed and assembled in accordance to one, or more embodiments; and

FIG. 5 is a flow chart for a method of a custom box system in accordance to one, or more embodiments.

Elements and acts in the figures are illustrated for simplicity and have not necessarily been rendered according to any particular sequence or embodiment.

### DETAILED DESCRIPTION

In the following description, and for the purposes of explanation, numerous specific details are set forth in order to provide a thorough understanding of the various aspects of the invention. It will be understood, however, by those skilled in the relevant arts, that the present invention may be practiced without these specific details. In other instances, known structures and devices are shown or discussed more generally in order to avoid obscuring the invention. In many cases, a description of the operation is sufficient to enable one to implement the various forms of the invention, particularly when the operation is to be implemented in software. It should be noted that there are many different and alternative configurations, devices and technologies to which the disclosed inventions may be applied. The full scope of the inventions is not limited to the examples that are described below.

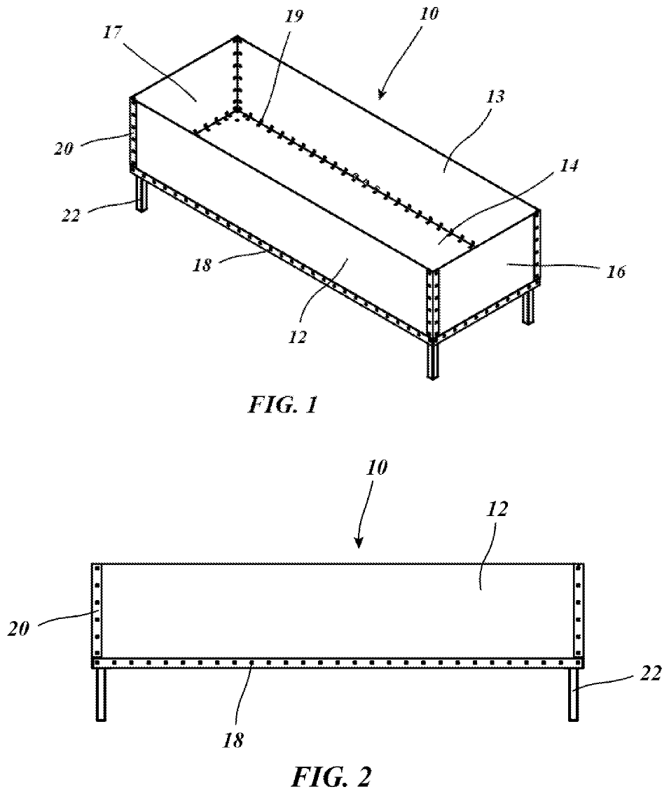

Referring initially to FIG. 1-3 a custom storage box is shown generally at 10. The custom storage box 10 can have a bottom member 14 wherein the bottom member can be attached to at least one first side member 12, 13 creating the width of the box and at least one side member 16, 17 creating the depth of the box wherein the first side member and the second side member can have the substantially the same height. The bottom member 14, first side members 12, 13 and the second side member 16, 17 can form the outer walls and bottom of the box. The bottom member 14, first side members 12, 13 and the second side member 16, 17 can be attached together by at least one attachment brackets 20 wherein the attachment brackets and the members can have a plurality of first holes 18 and a plurality of second holes 19.

The plurality of second holes 19 can be located on the bottom member 14, first side members 16, 17, and second side member 12, 13 wherein the plurality of first holes 18 can align with the plurality of second holes wherein a plurality of fasteners (not shown) can be attached to the bottom member and to the first side member and the second side member by the at least one attachment brackets 20 which can form the box fastened together. At least one leg member 22 can be located and attached to the bottom member 14 or in other embodiments can be attached to the first side member 12, 13, or the second side member 16, 17. The at least one leg member 22 can be a solid piece, multiple pieces, or hollow piece, or the like wherein the leg member can have one or more holes to attach itself to the first side member 12, 13, or the second side member 16, 17. In other embodiments, the at least one leg member 22 can be omitted. In embodiments, the user can specify the bottom member 14, first side members 12, 13 and the second side members 16, 17 length, width and thickness. The thickness of each member can be at least 0.025 inches up to at least 0.190 inches or any standard gauge of sheet metal and in the preferred embodiment the user chooses from a list of thicknesses from a computer app or webpage.

The attachment brackets 20 can be such as, for example, l-shaped rails, corner brackets, machine brackets, structural brackets, or the like. In certain embodiments, the attachment bracket 20 can have threaded holes in the plurality of holes for the fastener to attach to or the bottom member 14, first side members 12, 13 and second side members 16, 17 can have threaded holes in the plurality of holes so that the fastener can go through either the attachment bracket or the members. In other embodiments the fasteners can be attached to a nut to connect the bottom member 14, first side members 12, 13 and second side members 16, 17. The attachment brackets can be cut to the substantially the same dimensions of the width, depth, and height of the box.

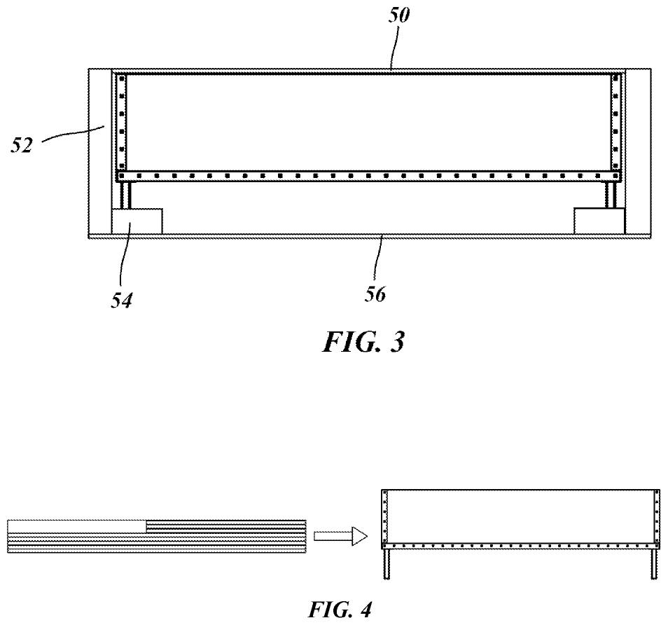

The custom storage box 10 including the bottom member 14, first side members 12, 13 and second side members 16, 17, and attachment brackets can be made from such as, for example, stainless steel, aluminum, carbon steel, steel, plastics or the like but in the preferred embodiment the user can choose what material type the custom storage box can be made out of. As shown in FIG. 3 the custom storage box 10 can fit into a user's truck bed 50 wherein the custom storage box can be manufactured from sheet metal to fit into any size of bed with the user's chosen specifications such as the user can measure the truck's height of the bed 52 and the length of the bed 56 and can fit behind the truck's wheel well in the truck bed. The custom storage box 10 can be cut from the flat sheet metal wherein when cut it can be put into a box, shipped to the user and assembled by the user as shown in FIG. 4.

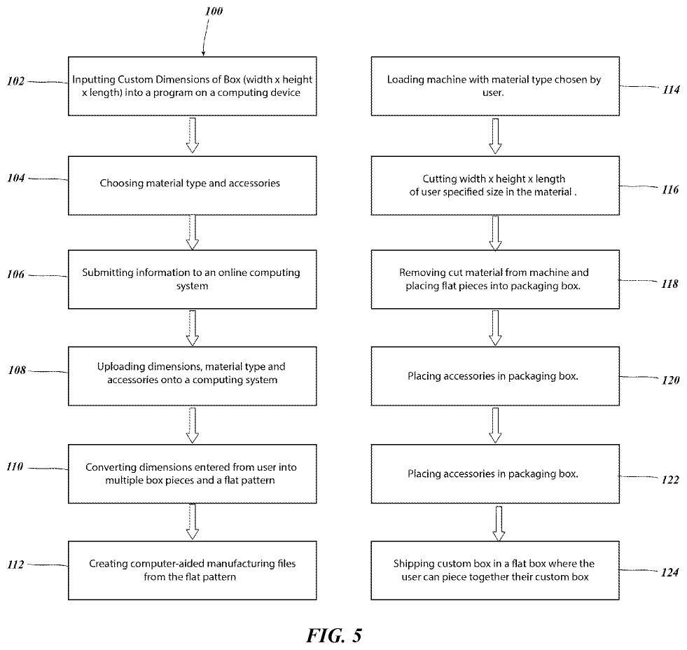

Referring to FIG. 5 the method of creating a custom storage box 100 comprising receiving input specifications of a box by a user into a program on a user's first computing device at step 102 wherein the user can choose a material type, design features and accessory types which can create user's customized information, at step 104. The material type can be such as, for example, stainless steel, aluminum, carbon steel, plastic, ceramic, or the like. The accessory type can be such as, for example, handles, lid, wheels, slide out drawers, inner compartments, inner storage shelves, or the like. Submitting the user's information to a second computing device wherein the second computing device can create a digital model of the custom storage box based on the user's information, at step 106. The digital model can be such as, for example, computer aided design model, vector drawing, or the like.

The user can submit their information to a second computing device wherein a digital model of the custom storage box can be generated based on the user's information wherein the information can be the dimensions of box, material type, accessories, and any other custom information of the box, at step 108. At step 110, the second computer can calculate and convert the user's input into dimensions for the box into a flat pattern. The second computer can be such as, for example, cloud computing, manufacturer's computer, a second user, or the like. At step 112 the second computing device can create a computer-aided manufacturing file from the flat pattern uploaded from the user wherein the computer-aided manufacturing file can be such as, for example, g-code, stereolithography, CAM files, CNC program files, or the like.

At step 114, the machine can be loaded with the chosen material type by the user. The material can be loaded by such as, for example, robot, by user, a machine, or the like. The machine can be a waterjet, laser cutting, machining center, or the like. The dimensions can be converted into a flat pattern wherein, at step 116, the user's dimensions can be cut out of the chosen material wherein the dimensions are width, height, and length of the box for each member. The calculated material requirements can include optimizing the material usage to minimize waste wherein the second computer can calculate the optimal layout for the dimensions of the box. The first computing device and the second computing device can be portable computing device, laptop computer, desktop computer, or smartphone.

At step 118, the access material can be removed, and the cut material can be removed from the machine and the cut material can placed into a packaging box at step 120. The packaging box can be such as, for example, folding cartons, corrugated boxes, rigid boxes, telescopic boxes or the like. The cut material can lay flat within the box allowing the box to be shipped easily as a flat pattern. At step 122, the accessories can be placed in the packaging box, and, at step 124, the custom box can be shipped to the user wherein the user puts together the box when received at their home or office space. The material type is stainless steel, aluminum, plastic, or carbon steel. The program can be on the world-wide web, cloud, LAN, WANN, or the like. The computer-aided manufacturing software can be located on the secondary computer or a third computer in which the computer-aided manufacturing software and machine are attached to. Shipping the custom box as a flat pattern can allow the user to order a custom box and save on shipping and allow the user to create a box that can fit the user's needs including such as, for example, a truck bed box, garden box, storage box, or the like.

In closing, it is to be understood that although aspects of the present specification are highlighted by referring to specific embodiments, one skilled in the art will readily appreciate that these disclosed embodiments are only illustrative of the principles of the subject matter disclosed herein. Therefore, it should be understood that the disclosed subject matter is in no way limited to a particular methodology, protocol, and/or reagent, etc., described herein. As such, various modifications or changes to or alternative configurations of the disclosed subject matter can be made in accordance with the teachings herein without departing from the spirit of the present specification. Lastly, the terminology used herein is for the purpose of describing particular embodiments only and is not intended to limit the scope of the present disclosure, which is defined solely by the claims. Accordingly, embodiments of the present disclosure are not limited to those precisely as shown and described.

Certain embodiments are described herein, including the best mode known to the inventors for carrying out the methods and devices described herein. Of course, variations on these described embodiments will become apparent to those of ordinary skill in the art upon reading the foregoing description. Accordingly, this disclosure includes all modifications and equivalents of the subject matter recited in the claims appended hereto as permitted by applicable law. Moreover, any combination of the above-described embodiments in all possible variations thereof is encompassed by the disclosure unless otherwise indicated herein or otherwise clearly contradicted by context.

What is claimed is:

1. A custom storage box comprising:
a bottom member wherein the bottom member is attached to at least one first side member creating a width of the box and at least one second side member creating a depth to the box wherein the first side member and second side member have substantially the same height;
at least one attachment brackets wherein the attachment brackets has a plurality of first holes;
a plurality of second holes located on the bottom member, first side member, and second side member wherein the plurality of first holes aligns with the plurality of second holes wherein a plurality of fasteners attaches the bottom member to the first side member and the second side member forming the box; and
at least one leg member located and attached to the bottom member.

2. The custom storage box according to claim 1, wherein the bottom member, first side member and second side member are sheet metal having a thickness of 0.025 to 0.190.

3. The custom storage box according to claim 1, wherein the attachment brackets are l-shaped rails, or corner brackets.

4. The custom storage box according to claim 1, wherein the custom storage box has a material type wherein the material type is stainless steel, aluminum, or carbon steel.

5. The custom storage box according to claim 1, wherein the attachment brackets are stainless steel, aluminum, or carbon steel.

6. The custom storage box according to claim 1, wherein the width and depth of the bottom member, first side member and second side member are chosen by a user.

7. The custom storage box according to claim 3, wherein the attachment brackets are cut to the substantially same dimension of the width, depth and height of the box.

8. The custom storage box according to claim 3, wherein the at least one leg member is a solid or l-shape metal piece.

9. The method of creating a custom storage box comprising:
receiving input specifications of a box from a user, including dimensions, material preferences, design features and accessories from a user's first computing device;
submitting the user's information to a second computing device wherein the second computing device creates a digital model of the custom storage box based on the user's information;
calculating and converting dimensions of the digital model into a flat pattern;
creating a computer-aided manufacturing file from the flat pattern;
loading a machine with the chosen material type by the user;
cutting the dimension on the material;
removing cut material from the machine and placing material into a packaging box;
placing accessories in packaging box; and
shipping custom box to the user wherein the user puts together the box when received.

10. The method of creating a custom storage box according to claim 1, wherein the first computing device and the second computing device are portable computing device, laptop computer, desktop computer, or smartphone.

11. The method of creating a custom storage box according to claim 9, wherein the machine is a waterjet, laser cutting, or machining center.

12. The method of creating a custom storage box according to claim 9, wherein the material type is stainless steel, aluminum, or carbon steel

13. The method of creating a custom storage box according to claim 9, wherein the program is located on the cloud service.

14. The method of creating a custom storage box according to claim 9, wherein the computer-aided manufacturing software is located on the secondary computer or a third computer in which the computer-aided manufacturing software and machine are attached to.
